(19) United States
(12) Patent Application Publication
(10) Pub. No.: US 2024/0266215 A1
(43) Pub. Date: Aug. 8, 2024

(54) LOW STRESS TUNGSTEN LAYER DEPOSITION

(71) Applicant: Applied Materials, Inc., Santa Clara, CA (US)

(72) Inventors: Xi CEN, San Jose, CA (US); Yang LI, Sunnyvale, CA (US); Kai WU, Palo Alto, CA (US); Mehran BEHDJAT, Santa Clara, CA (US); Jallepally RAVI, San Ramon, CA (US)

(21) Appl. No.: 18/107,326

(22) Filed: Feb. 8, 2023

(51) Int. Cl. H01L 21/768; H01L 21/3205

(52) U.S. Cl. CPC H01L 21/76876; H01L 21/32051; H01L 21/76856; H01L 21/76877

(57) ABSTRACT

A method of forming a structure on a substrate, includes forming a nucleation layer within an opening of the substrate within a processing chamber. The method further includes forming a passivation layer on at least a portion of the nucleation layer by introducing radical treatment into the processing chamber. The method further includes forming a tungsten fill layer within the opening over the passivation layer and the nucleation layer, wherein the tungsten fill layer is formed by a plurality of treatment cycles. Each treatment cycle includes pulsing a first gas at the substrate for a pulse time duration while concurrently flowing a second gas over the substrate, and purging the first gas and the second gas by flowing a purge gas over the substrate for a purge time duration.

### BACKGROUND

### Field

Embodiments of the present disclosure generally relate to methods used in electronic device manufacturing, and more particularly, to methods used for forming tungsten features in a semiconductor device.

### Description of the Related Art

Tungsten (W) is widely used in integrated circuit (IC) device manufacturing to form conductive features where relatively low electrical resistance and relativity high resistance to electromigration are desired. For example, tungsten may be used as a metal fill material to form source contacts, drain contacts, metal gate fill, gate contacts, interconnects (e.g., horizontal features formed in a surface of a dielectric material layer), and vias (e.g., vertical features formed through a dielectric material layer to connect other interconnect features disposed there above and there below).

Due to its relatively low resistivity, tungsten is also commonly used to form bit lines and word lines used to address individual memory cells in a memory cell array of a three-dimensional NAND (3D NAND) device. 3D NAND structures include tiers of horizontal arrays that can be stacked by depositing layers in sequence. Channels can be formed through the stack of films and filled with tungsten. In some cases, the channel sidewall widths can vary between tiers. During filling the channel, the tungsten fill layer can deposit an upper portion of the channel quicker than a lower portion due to the varying channel sidewall widths and higher concentration of precursor gases used to deposit the tungsten fill layer. This can cause void formation within portions of the channels, particularly for channels disposed in structures having two or more tiers, and particularly for high aspect ratio features. Additionally, conventional methods to deposit the tungsten within the channel result in a tungsten gap fill with high internal stress. This stress can deform (e.g., warp, bow, crack) the substrate.

Accordingly, there is a need for processes to deposit a tungsten gap fill within channels in multi-tier structures that is free or substantially free of voids and seams and has low resistivity. There is also a need in the art to deposit a tungsten gap fill with low to no internal stress.

### SUMMARY

Embodiments described herein generally relate to systems and methods used for forming tungsten features in a semiconductor device. More particularly, embodiments herein provide for processes and methods to form a low stress tungsten structure.

In one embodiment, a method of forming a structure on a substrate, includes forming a nucleation layer within an opening of the substrate within a processing chamber. The method further includes forming a passivation layer on at least a portion of the nucleation layer by introducing radical treatment into the processing chamber. The method further includes forming a tungsten fill layer within the opening over the passivation layer and the nucleation layer, wherein the tungsten fill layer is formed by a plurality of treatment cycles. Each treatment cycle includes pulsing a first gas at the substrate for a pulse time duration while concurrently flowing a second gas over the substrate, and purging the first gas and the second gas by flowing a purge gas over the substrate for a purge time duration.

In one embodiment, a method of forming a structure on a substrate includes depositing a tungsten fill layer into an opening of the substrate having an internal stress less than 200 MPa. The tungsten fill layer is formed by a plurality of treatment cycles, each treatment cycle including pulsing a first gas at the substrate for a pulse time duration while concurrently flowing a second gas over the substrate, and purging the first gas and the second gas by flowing a purge gas over the substrate for a purge time duration.

In one embodiment, a method of forming a structure on a substrate includes forming a nucleation layer on the substrate. A first portion of the nucleation layer is deposited in an opening of the substrate and a second portion of the nucleation layer is deposited on a field of the substrate. The method further includes forming a passivation layer on the nucleation layer by exposing the nucleation layer to a radical treatment. The passivation layer prevents tungsten deposition on the second portion of the nucleation layer. The method further includes forming a tungsten fill layer within the opening over the passivation layer and the nucleation layer. The tungsten fill layer is formed by a plurality of treatment cycles, each treatment cycle including pulsing a first gas at the substrate for a pulse time duration while concurrently flowing a second gas over the substrate, and purging the first gas and the second gas by flowing a purge gas over the substrate for a purge time duration.

### BRIEF DESCRIPTION OF THE DRAWINGS

So that the manner in which the above recited features of the present disclosure can be understood in detail, a more particular description of the disclosure, briefly summarized above, may be had by reference to embodiments, some of which are illustrated in the appended drawings. It is to be noted, however, that the appended drawings illustrate only exemplary embodiments of the disclosure and are therefore not to be considered limiting of its scope, as the disclosure may admit to other equally effective embodiments.

FIG. 1 is a schematic section view of a portion of a substrate illustrating undesirable voiding or seaming in conventionally formed tungsten features.

FIG. 2A is a schematic view of a processing system that may be used to implement the methods set forth herein, according to one embodiment.

FIG. 2B is a close-up sectional view of a portion of the processing system shown in FIG. 2A.

FIG. 3 is a diagram illustrating a method of processing a substrate, according to one embodiment.

FIG. 4A is a schematic sectional view of a portion of a substrate including a substrate to be processed by a method described herein, according to one embodiment.

FIG. 4B is a schematic sectional view of the substrate showing an adhesion layer deposited thereon, according to one embodiment.

FIG. 4C is a schematic sectional view of the substrate showing a nucleation layer deposited on the adhesion layer, according to one embodiment.

FIG. 4D is a schematic sectional view of the substrate showing a passivation layer formed on the nucleation layer, according to one embodiment.

FIG. 4E is a schematic sectional view of the substrate showing a tungsten gap fill layer, according to one embodiment.

FIG. 5 shows a graph showing the stress of different tungsten gap fill layers deposited on a substrate formed by different processes.

To facilitate understanding, identical reference numerals have been used, where possible, to designate identical elements that are common to the figures. It is contemplated that elements and features of one embodiment may be beneficially incorporated in other embodiments without further recitation.

### DETAILED DESCRIPTION

Embodiments herein are generally directed to electronic device manufacturing and, more particularly, to systems and methods for forming low resistivity tungsten features in a semiconductor device manufacturing scheme.

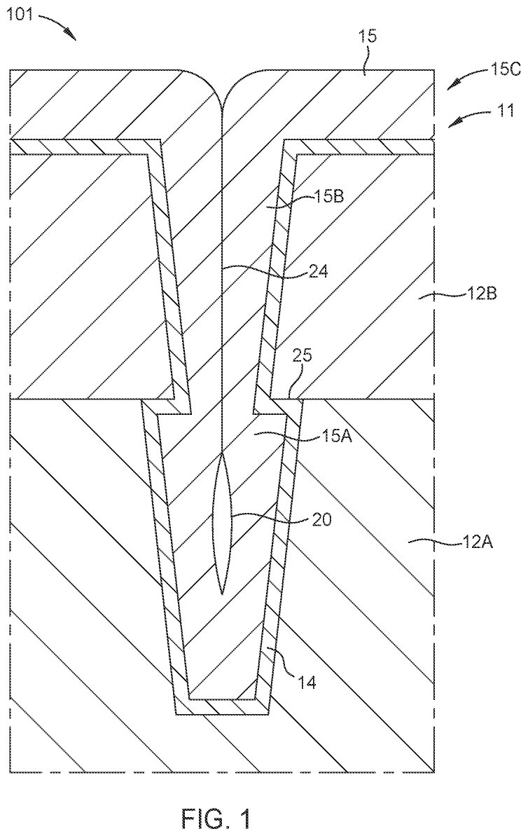

FIG. 1 is a schematic cross-sectional view of a substrate 101 illustrating an undesirable void 20 formed during a conventional tungsten deposition process. Here, the substrate 101 includes a patterned surface 11 disposed within a plurality of tier layers, such as a first tier layer 12A and a second tier layer 12B. In some embodiments, the first tier layer 12A is a first dielectric layer and the second tier layer 12B is a second dielectric layer. In some embodiments, the substrate 101 includes a plurality of alternating first and second tier layers. The patterned surface 11 includes at least one opening having a high aspect ratio opening formed therein (shown filled with a portion of a tungsten layer 15), an adhesion layer 14 deposited on the tier layers 12A, 12B to line the opening, and the tungsten layer 15 deposited on the adhesion layer 14. The tungsten layer 15 illustrated in FIG. 1 is formed using a conventional deposition process, e.g., a chemical vapor deposition (CVD) or atomic layer deposition (ALD) process where tungsten is conformally deposited (grown) on the patterned surface 11 to fill the opening. The tungsten layer 15 forms a tungsten feature 15A within the first tier layer 12A, a tungsten feature 15B within the second tier layer 12B and an overburden of material (tungsten overburden layer 15C) on the field of the patterned surface 11. In one example, the first dielectric layer and the second dielectric layer can include a silicon oxide (SiOₓ) and/or a silicon nitride (SiN).

In FIG. 1, the opening has a non-uniform profile that is wider at the surface of the substrate 101 and tapers as the opening extends from the surface inwardly into the second layer 12B. At an interface 25 of the first and second tier layers, the width of the second tier layer 12B is narrower than the width of the first tier layer 12A disposed inward from the second tier layer 12B. As shown, interface portions of the conformal tungsten layer 15 have grown together to block or “pinch off” the entrance to the opening disposed in the first tier 12A before the opening could be completely filled, thus causing the undesirable void 20, i.e., an absence of tungsten material, in the tungsten feature 15A. In addition to voids, undesirable seams (e.g., 24) can occur in tungsten features, as shown within the second tier 12B using a conventional tungsten deposition process. The void 20 and seam 24 are vulnerable to corrosion from the chemically active components of tungsten chemical mechanical polishing (CMP) polishing fluid, which may cause undesirable loss of tungsten material from the feature 15A, 15B if the seam 24 or void 20 is exposed during the CMP process. Additionally, conventional tungsten deposition processes result in a tungsten layer 15 with high internal stress that can deform the first tier layer 12A and a second tier layer 12B of the substrate 101. For example, the stress can be about or exceed 1600 MPa.

Embodiments described herein form a tungsten gap fill deposited from the bottom-up within an opening of a substrate with reduced stress and reduced instances of voids. The methods and systems provided herein are particularly useful for tungsten gap fill for high aspect ratio features, such as about 25:1 or greater, such as about 30:1 to about 100:1, such as about 50:1 to about 80:1. The aspect ratio refers to a ratio of total height to an average width or diameter of the feature. Additionally, embodiments herein provide a processing system that is configured to perform a combination of the individual aspects of the methods without transferring a substrate between processing chambers, thus improving overall substrate processing throughput and capacity for the tungsten gap fill processing schemes described herein.

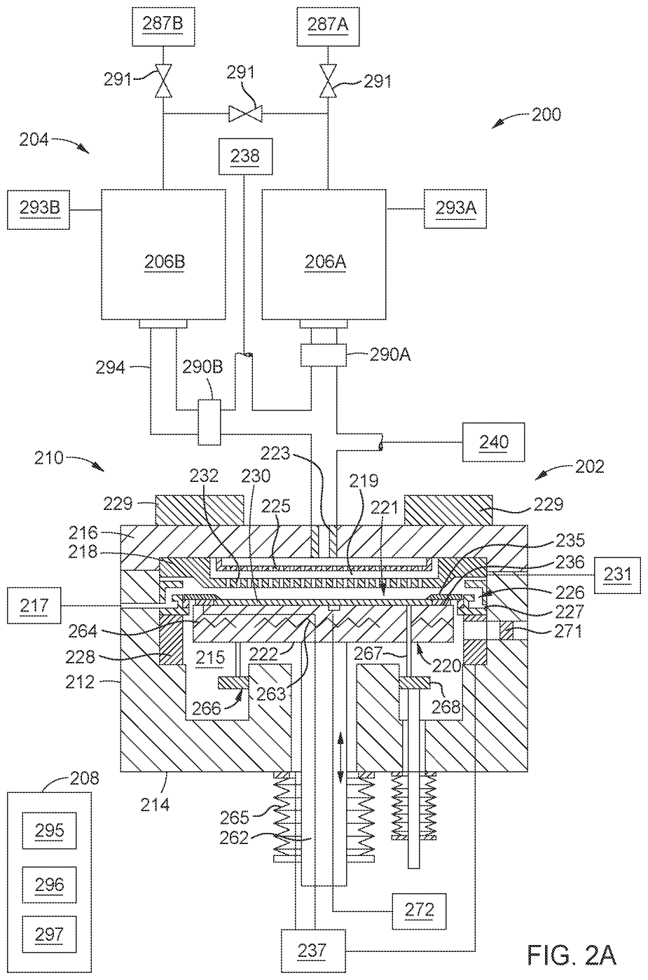

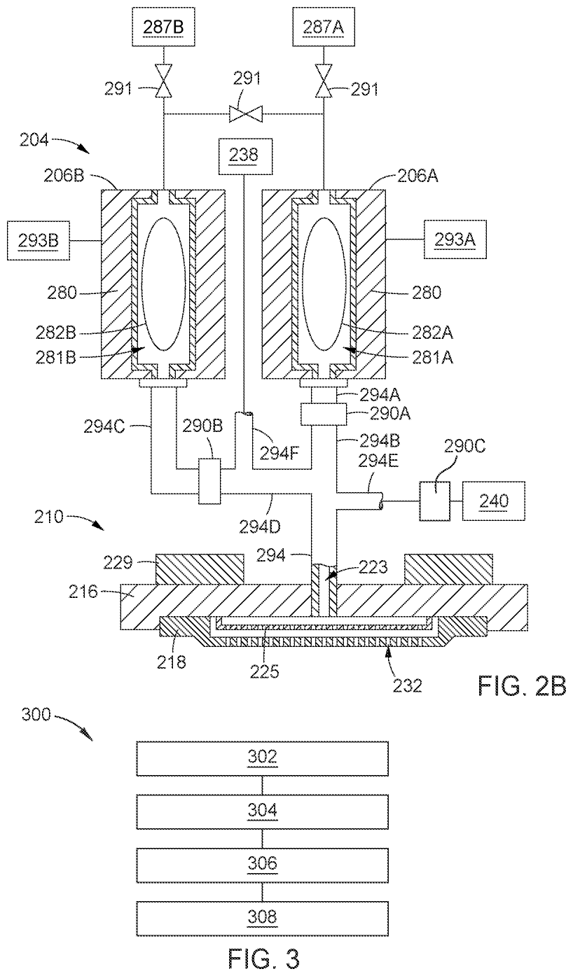

FIG. 2A schematically illustrates a processing system 200 that may be used to perform a bottom-up tungsten gap fill substrate processing method described herein. Here, the processing system 200 is configured to provide the different processing conditions desired for forming an adhesion layer, nucleation layer, passivation layer, and tungsten gap-fill layer on a substrate within a single processing chamber 202, i.e., without transferring a substrate between a plurality of processing chambers.

As shown in FIG. 2A, the processing system 200 includes the processing chamber 202, a gas delivery system 204 fluidly coupled to the processing chamber 202, and a system controller 208. The processing chamber 202 (shown in cross-section in FIG. 2A) includes a chamber lid assembly 210, one or more sidewalls 212, and a chamber base 214, which collectively define a processing volume 215. The processing volume 215 is fluidly coupled to an exhaust 217, such as one or more vacuum pumps, used to maintain the processing volume 215 at a process pressure, such as sub-atmospheric pressure conditions, and to evacuate processing gases and processing by-products therefrom.

The chamber lid assembly 210 includes a lid plate 216 and a showerhead 218 coupled to the lid plate 216 to define a gas distribution volume 219 therewith. Here, the lid plate 216 is maintained at a desired temperature using one or more heaters 229 thermally coupled thereto. The showerhead 218 faces a substrate support assembly 220 disposed in the processing volume 215. As discussed below, the substrate support assembly 220 is configured to move a substrate support 222, and thus a substrate 230 disposed on the substrate support 222, between a raised substrate processing position (as shown) and a lowered substrate transfer position (not shown). When the substrate support assembly 220 is in the raised substrate processing position, the showerhead 218 and the substrate support 222 define a processing region 221.

The gas delivery system 204 is fluidly coupled to the processing chamber 202 through a gas inlet 223 that is disposed through the lid plate 216. Processing or cleaning gases delivered, by use of the gas delivery system 204, flow through the gas inlet 223 into the gas distribution volume 219 and are distributed into the processing region 221 through a plurality of openings 232 in the showerhead 218. In some embodiments, the chamber lid assembly 210 further includes a perforated blocker plate 225 disposed between the gas inlet 223 and the showerhead 218. In those embodiments, gases flowed into the gas distribution volume 219 are first diffused by the blocker plate 225 to, together with the showerhead 218, provide a more uniform or desired distribution of gas flow into the processing region 221.

The processing gases and processing by-products are evacuated radially outward from the processing region 221 through an annular channel 226 that surrounds the processing region 221. The annular channel 226 may be formed in a first annular liner 227 disposed radially inward of the one or more sidewalls 212 (as shown) or may be formed in the one or more sidewalls 212. In some embodiments, the processing chamber 202 includes one or more second liners 228, which are used to protect the interior surfaces of the one or more sidewalls 212 or chamber base 214 from corrosive gases and/or undesired material deposition.

In some embodiments, a purge gas source 237 in fluid communication with the processing volume 215 is used to flow a chemically inert purge gas, such as Argon (Ar), into a region disposed beneath the substrate support 222, e.g., through the opening in the chamber base 214 surrounding a support shaft 262. The purge gas may be used to create a region of positive pressure below the substrate support 222 (when compared to the pressure in the processing region 221) during substrate processing. Typically, purge gas introduced through the chamber base 214 flows upwardly therefrom and around the edges of the substrate support 222 to be evacuated from the processing volume 215 through the annular channel 226. The purge gas reduces undesirable material deposition on surfaces beneath the substrate support 222 by reducing and/or preventing the flow of material precursor gases thereinto.

The substrate support assembly 220 includes the movable support shaft 262 that sealingly extends through the chamber base 214, such as being surrounded by a bellows 265 in the region below the chamber base 214, and the substrate support 222, which is disposed on the movable support shaft 262. To facilitate substrate transfer to and from the substrate support 222, the substrate support assembly 220 includes a lift pin assembly 266 comprising a plurality of lift pins 267 coupled to or disposed in engagement with a lift pin hoop 268. The plurality of lift pins 267 are movably disposed in openings formed through the substrate support 222. When the substrate support 222 is disposed in a lowered substrate transfer position (not shown), the plurality of lift pins 267 extend above a substrate receiving surface of the substrate support 222 to lift a substrate 230 therefrom and provide access to a backside (non-active) surface of the substrate 230 by a substrate handler (not shown). When the substrate support 222 is in a raised or processing position (as shown), the plurality of lift pins 267 recede beneath the substrate receiving surface of the substrate support 222 to allow the substrate 230 to rest thereon.

The substrate 230 is transferred to and from the substrate support 222 through a door 271, e.g., a slit valve disposed in one of the one or more sidewalls 212. Here, one or more openings in a region surrounding the door 271, e.g., openings in a door housing, are fluidly coupled to the purge gas source 237, e.g., an Ar gas source. The purge gas is used to prevent processing and cleaning gases from contacting and/or degrading a seal surrounding the door, thus extending the useful lifetime thereof.

The substrate support 222 is configured for vacuum chucking where the substrate 230 is secured to the substrate support 222 by applying a vacuum to an interface between the substrate 230 and the substrate receiving surface. The vacuum is applied by use of a vacuum source 272 fluidly coupled to one or more channels or ports formed in the substrate receiving surface of the substrate support 222. In other embodiments, e.g., where the processing chamber 202 is configured for direct plasma processing, the substrate support 222 may be configured for electrostatic chucking. In some embodiments, the substrate support 222 includes one or more electrodes (not shown) coupled to a bias voltage power supply (not shown), such as a continuous wave (CW) RF power supply or a pulsed RF power supply, which supplies a bias voltage thereto.

As shown, the substrate support assembly 220 features a dual-zone temperature control system to provide independent temperature control within different regions of the substrate support 222. The different temperature-controlled regions of the substrate support 222 correspond to different regions of the substrate 230 disposed thereon. Here, the temperature control system includes a first heater 263 and a second heater 264. The first heater 263 is disposed in a central region of the substrate support 222, and the second heater 264 is disposed radially outward from the central region to surround the first heater 263. In other embodiments, the substrate support 222 may have a single heater or more than two heaters.

In some embodiments, the substrate support assembly 220 further includes an annular shadow ring 235, which is used to prevent undesired material deposition on a circumferential bevel edge of the substrate 230. During substrate transfer to and from the substrate support 222, i.e., when the substrate support assembly 220 is disposed in a lowered position (not shown), the shadow ring 235 rests on an annular ledge within the processing volume 215. When the substrate support assembly 220 is disposed in a raised or processing position, the radially outward surface of the substrate support 222 engages with the annular shadow ring 235 so that the shadow ring 235 circumscribes the substrate 230 disposed on the substrate support 222. Here, the shadow ring 235 is shaped so that a radially inward facing portion of the shadow ring 235 is disposed above the bevel edge of the substrate 230 when the substrate support assembly 220 is in the raised substrate processing position.

In some embodiments, the substrate support assembly 220 further includes an annular purge ring 236 disposed on the substrate support 222 to circumscribe the substrate 230. In those embodiments, the shadow ring 235 may be disposed on the purge ring 236 when the substrate support assembly 220 is in the raised substrate processing position. Typically, the purge ring 236 features a plurality of radially inward facing openings that are in fluid communication with the purge gas source 237. During substrate processing, a purge gas flows into an annular region defined by the shadow ring 235, the purge ring 236, the substrate support 222, and the bevel edge of the substrate 230 to prevent processing gases from entering the annular region and causing undesired material deposition on the bevel edge of the substrate 230.

In some embodiments, the processing chamber 202 is configured for direct plasma processing. In those embodiments, the showerhead 218 may be electrically coupled to a first power supply 231, such as an RF power supply, which supplies power to ignite and maintain a plasma of processing gases flowed into the processing region 221 through capacitive coupling therewith. In some embodiments, the processing chamber 202 comprises an inductive plasma generator (not shown), and a plasma is formed through inductively coupling an RF power to the processing gas.

Referring to FIGS. 2A and 2B, the gas delivery system 204 includes one or more remote plasma sources, here a first and second radical generator 206A-B, a deposition gas source 240, and a conduit system 294 (e.g., the plurality of conduits 294A-F) fluidly coupling the radical generators 206A-B and the deposition gas source 240 to the lid assembly 210. Although the gas delivery system 204 shown includes two radical generators 206A-B, the processes describe herein could also be practiced using a gas delivery system 204 having only a single radical generator 206A. The gas delivery system 204 further includes a plurality of isolation valves, here the first and second valves 290A-B, respectively disposed between the radical generators 206A-B and the lid plate 216, which may be used to fluidly isolate each of the radical generators 206A-B from the processing chamber 202 and from one another.

Each of the radical generators 206A-B features a chamber body 280 that defines respective first and second plasma chamber volumes 281A-B (FIG. 2B). Each of the radical generators 206A-B is coupled to a respective power supply 293A-B. The power supplies 293A-B are used to ignite and maintain a plasma 282A-B of gases delivered to the plasma chamber volumes 281A-B from a corresponding first or second gas source 287A-B fluidly coupled thereto. The first radical generator 206A may be used to ignite and maintain a treatment plasma 282A from a non-halogen-containing gas mixture delivered to the first plasma chamber volume 281A from the first gas source 287A. In some embodiments, the first radical generator 206A generates an activated species, e.g., treatment radicals, used to treat the substrate to inhibit the deposition of tungsten thereon, such as by the formation of a passivation layer. The treatment radicals may be a non-halogen nitrogen-containing gas, such as nitrogen gas (N₂), ammonia (NH₃), or other nitrogen containing gas. The treatment radicals may be a combination of different non-halogen nitrogen containing gases. In some embodiments, the treatment radicals may be a nitrogen containing gas that includes a halogen, such as nitrogen trifluoride (NF₃). The second radical generator 206B may be used to generate cleaning radicals used in a chamber clean process by igniting and maintaining a cleaning plasma 282B from a halogen-containing gas mixture delivered to the second plasma chamber volume 281B from the second gas source 287B.

Typically, nitrogen treatment radicals have a relativity short lifetime (when compared to halogen cleaning radicals) and may exhibit a relatively high sensitivity to recombination from collisions with surfaces in the gas delivery system 204, such as the conduit system 294, and/or with other species of the treatment plasma effluent. Thus, in embodiments herein, the first radical generator 206A is typically positioned closer to the gas inlet 223 than the second radical generator 206B, e.g., to provide a relatively shorter travel distance from the first plasma chamber volume 281A to the processing region 221. In some embodiments, the first radical generator 206A and first gas source 287A are attached to the chamber lid assembly 210 or a superstructure of the processing chamber 202.

In some embodiments, the first radical generator 206A is also fluidly coupled to the second gas source 287B, which delivers a halogen-containing conditioning gas to the first plasma chamber volume 281A to be used in a plasma source condition process. In those embodiments, the gas delivery system 204 may further include a plurality of diverter valves 291, which are operable to direct the halogen-containing gas mixture from the second gas source 287B to the first plasma chamber volume 281A.

Suitable remote plasma sources which may be used for one or both of the radical generators 206A-B include radio frequency (RF) or very high radio frequency (VHRF) capacitively coupled plasma (CCP) sources, inductively coupled plasma (ICP) sources, microwave-induced (MW) plasma sources, electron cyclotron resonance (ECR) chambers, or high-density plasma (HDP) chambers.

As shown, the first radical generator 206A is fluidly coupled to the processing chamber 202 by use of first and second conduits 294A-B, which extend upwardly from the gas inlet 223 to connect with an outlet of the first plasma chamber volume 281A. A first valve 290A, disposed between the first and second conduits 294A-B, is used to selectively fluidly isolate the first radical generator 206A from the processing chamber 202 and the other portions of the gas delivery system 204. Typically, the first valve 290A is closed during the chamber clean process to prevent activated cleaning gases, e.g., halogen radicals, from flowing into the first plasma chamber volume 281A and damaging the surfaces thereof.

The second radical generator 206B is fluidly coupled to the second conduit 294B, and thus the processing chamber 202, by use of third and fourth conduits 294C-D. The second radical generator 206B is selectively isolated from the processing chamber 202 and from the other portions of the gas delivery system 204 by use of a second valve 290B that is disposed between the third and fourth conduits 294C-D.

Deposition gases, e.g., tungsten-containing precursors and reducing agents, are delivered from the deposition gas source 240 to the processing chamber 202 using a fifth conduit 294E. As shown, the fifth conduit 294E is coupled to the second conduit 294B at a location proximate to the gas inlet 223 so that the first and second valves 290A-B may be used to respectively isolate the first and second radical generators 206A-B from deposition gases introduced into the processing chamber 202. A third valve 290C is disposed in the fifth conduit 294E to selectively isolate the deposition gas source 240 from the first and second radical generators 206A-B as well as to selectively allow an amount of deposition gas to flow through the fifth conduit 294E and into the processing region 221. In some embodiments, the gas delivery system 204 further includes a sixth conduit 294F which is coupled to the fourth conduit 294D at a location proximate to the second valve 290B. The sixth conduit 294F, is fluidly coupled to a bypass gas source 238, e.g., an Argon (Ar) gas source, which may be used to periodically purge portions of the gas delivery system 204 of undesired residual cleaning, inhibition, and deposition gases.

In some embodiments, the deposition gas source 240 is attached to the chamber lid assembly 210 or a superstructure of the processing chamber 202. In some embodiments, the deposition gas source 240 is a plurality of different deposition gas reservoirs connected to the conduit system 294 by a separate conduit, and each respective deposition gas reservoir may have an accompanying flow control valve. Each separate deposition gas reservoir may be attached to the chamber lid assembly 210 or the superstructure of the processing chamber 202.

Operation of the processing system 200 is facilitated by the system controller 208 (FIG. 2A). The system controller 208 includes a programmable central processing unit, here the CPU 295, which is operable with a memory 296 (e.g., non-volatile memory) and support circuits 297. The CPU 295 is one of any form of general-purpose computer processor used in an industrial setting, such as a programmable logic controller (PLC), for controlling various chamber components and sub-processors. The memory 296, coupled to the CPU 295, facilitates the operation of the processing chamber. The support circuits 297 are conventionally coupled to the CPU 295 and comprise cache, clock circuits, input/output subsystems, power supplies, and the like, and combinations thereof coupled to the various components of the processing system 200 to facilitate control of substrate processing operations therewith.

The instructions in memory 296 are in the form of a program product, such as a program that implements the methods of the present disclosure. In one example, the disclosure may be implemented as a program product stored on computer-readable storage media for use with a computer system. The program(s) of the program product define functions of the embodiments (including the methods described herein). Thus, the computer-readable storage media, when carrying computer-readable instructions that direct the functions of the methods described herein, are embodiments of the present disclosure.

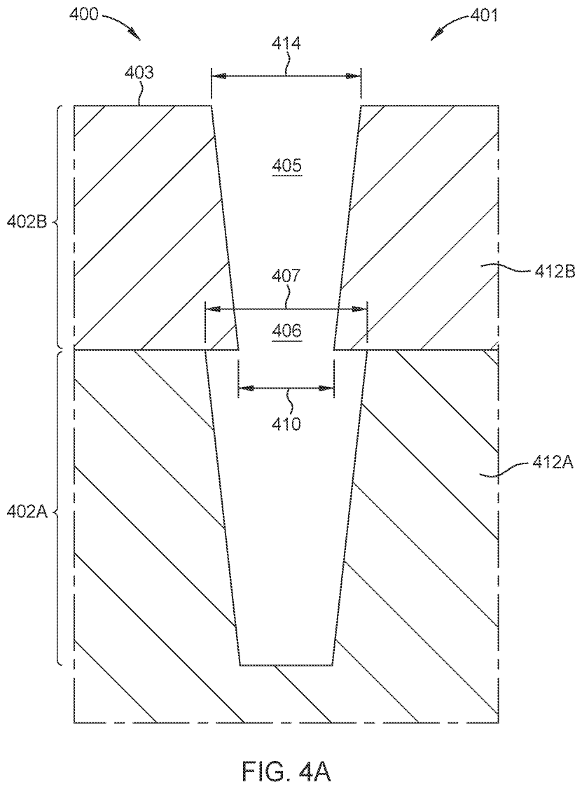

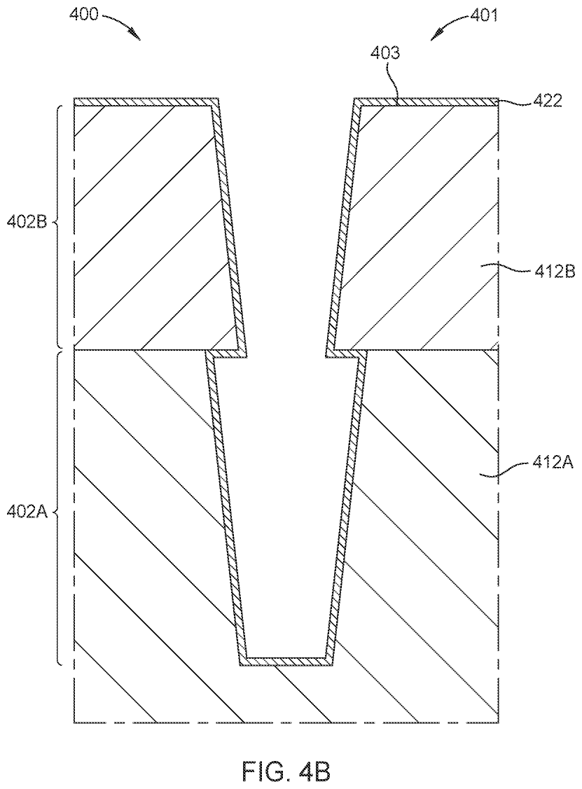

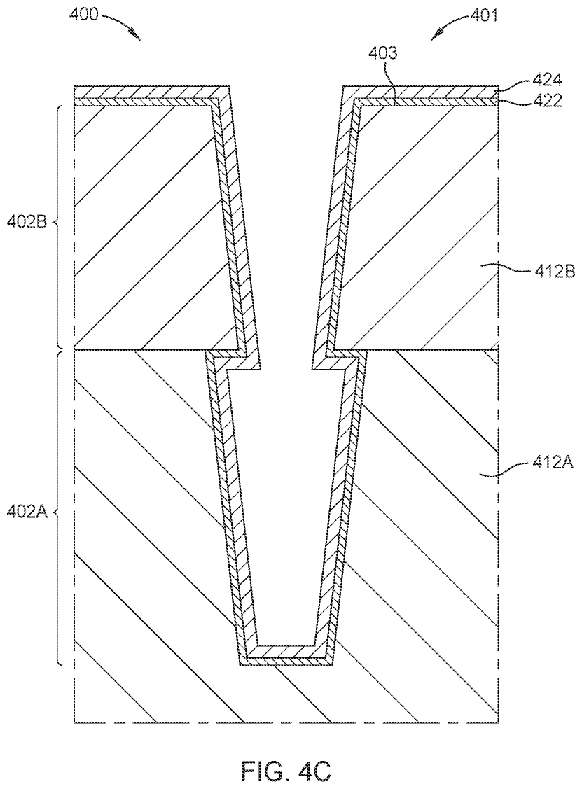

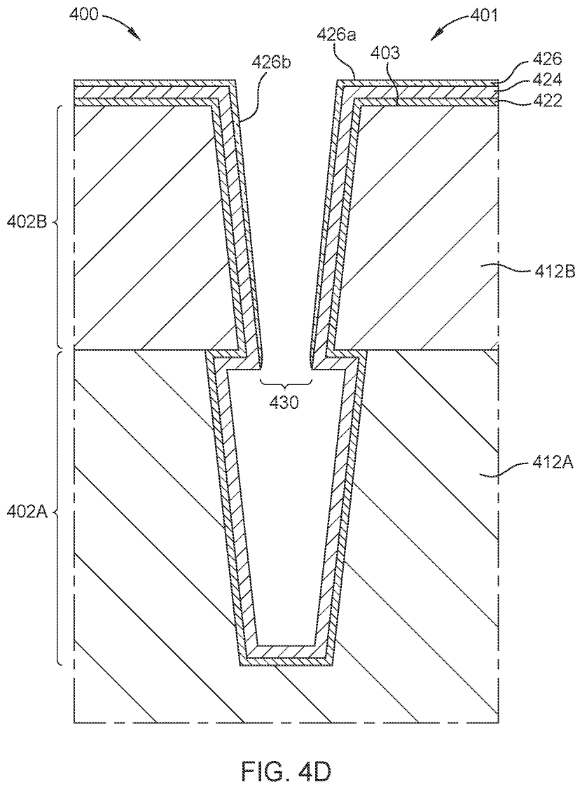

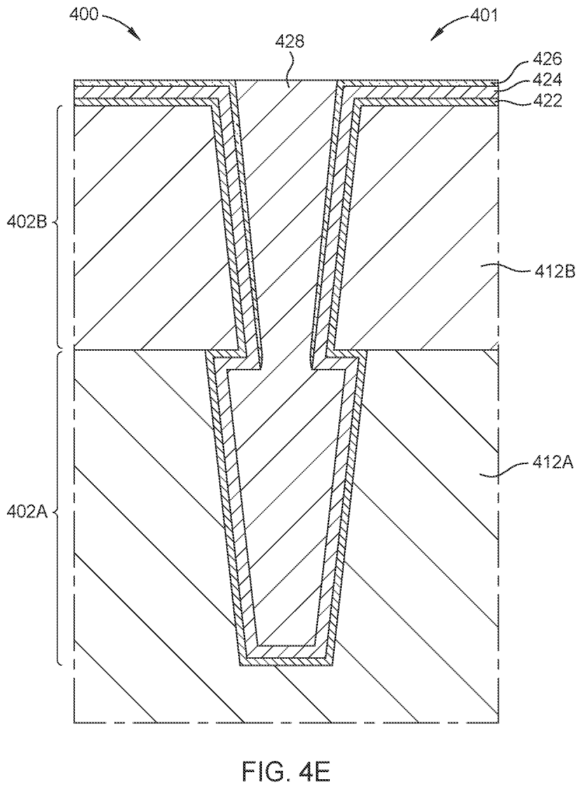

FIG. 3 is a diagram illustrating a process 300 used to process a substrate according to some embodiments, which may be performed using the processing system 200. FIGS. 4A-4E are schematic sectional views of a portion of an exemplary substrate 400 illustrating aspects at different stages of the process 300.

An adhesion layer 422 is formed on the substrate 400 as depicted by activity 302 after the substrate 400 is placed on the substrate receiving surface of the substrate support 222 within the processing chamber 202. Then, as depicted by activity 304, a nucleation layer 424 is deposited on the adhesion layer 422. The substrate 400 is then subjected to a radical treatment, where the substrate 400 is treated with a treatment gas that includes an activated species, to form a passivation layer 426 as depicted by activity 306. A tungsten gap fill layer 428 is then deposited by pulse CVD as depicted by activity 308. The tungsten gap fill layer 428 is deposited from the bottom up and is substantially or completely free of voids or seams. The process 300 will be explained in more detail below.

FIG. 4A illustrates an exemplary substrate 400. The substrate 400 features a patterned surface 401 including a first tier layer 412A and a second tier layer 412B having a plurality of openings 405 (one shown) formed therein. In some embodiments, the plurality of openings 405 include one or a combination of high aspect ratio via or trench openings having a width (e.g., each of 407, 414) of about 100 nm to about 400 nm, such as about 200 nm to about 300 nm and a depth (e.g., each of 402A or 402B or either of 402A or 402B) of about 2 μm to about 8 μm, such as about 3 μm to about 6 μm. In some embodiments, the plurality of openings includes at least one opening with a width 410 of a narrowest portion of the opening of about 50 nm to about 200 nm, such as about 75 nm to about 125 nm. In some embodiments, individual openings 405 may have an aspect ratio (depth to width ratio) of about 10:1 or more, such as about 25:1 or more, such as about 30:1 to about 100:1, such as about 40:1 to about 60:1. In some embodiments, the vias or trench openings include aspect ratios of about 20:1 to about 40:1. An opening disposed within the first tier 412A is referred to as first tier opening 402A and an opening disposed within the second tier 412B is referred to as a second tier opening 402B. The first and second tier openings 402A and 402B together form a single contiguous opening 405. The uppermost portion of the first tier opening 402A interfaces the lowermost portion of the second tier opening 402B at interface 406.

The width 407 of the uppermost portion of the first tier opening is greater than a width 410 of the lowermost portion of the second tier opening 402B at the interface 406. In some embodiments, the width 407 is about 5% to about 100% greater than the width 410, such as about 10% greater to about 50% greater. For example, width 410 can be about 50 nm to about 300 nm, such as about 75 nm to about 125 nm and the width of 407 can be about 70 nm to about 400 nm, such as about 150 nm to about 250 nm. In some embodiments, for each tier, a widest portion of the tier, such as the uppermost portion 414 of the second tier 402B is about 5% to about 100% greater than a narrowest portion of the tier, such as a lowermost portion 410 of the second tier 402B, such as about 10% greater to about 50% greater. In some embodiments, a height of the first tier opening 402A is substantially the same, is less than, or greater than a height of the second tier opening 402B. Without being bound by theory, it is believed that sudden differences in opening widths at interfaces can cause a pinching effect as the tungsten gap-fill layer is deposited. The process 300 described herein enables the formation of a tungsten gap fill layer 428 that fills the opening 405 without the formation of voids.

As shown by activity 302 in FIG. 3 and referring to FIG. 4B, the process 300 begins by depositing the adhesion layer 422 on the pattern surface 401 within the processing chamber 202. The adhesion layer 422 is composed of a material that prevents or limits the diffusion of tungsten into underlying material, in addition to promoting the nucleation of tungsten. The adhesion layer 422 may be a titanium nitride (TiN) layer. As shown in FIG. 4B, the patterned surface 401 includes the adhesion layer 422, deposited on the first tier layer 412A and the second tier layer 412B to conformally line the opening 405 and facilitate the subsequent deposition of a tungsten nucleation layer 424. In some embodiments, the adhesion layer 422 is deposited to a thickness of between about 20 angstroms (Å) and about 150 Å, such as about 30 Å to about 100 Å. The adhesion layer 422 may be formed using atomic layer deposition (ALD), a physical vapor deposition (PVD) process, or a chemical vapor deposition (CVD) process by the processing system 200. For example, the adhesion layer 422 may be a titanium nitride layer formed by the use of titanium containing precursor and nitrogen containing precursor flowing from the deposition gas source 240 to the processing region 221. For example, the adhesion layer 422 may be formed flowing titanium tetrachloride (TiCl₄) and ammonia (NH₃) from the deposition gas source 240 into the processing region 221 to react therein to form titanium nitride.

As shown by activity 304, a nucleation layer 424 is deposited on the adhesion layer 422. A portion of an exemplary substrate 400 having the nucleation layer 424 formed thereon is schematically illustrated in FIG. 4C. The nucleation layer 424 can be formed using any process capable of forming a tungsten nucleation layer. In some embodiments, the nucleation layer 424 is deposited using an atomic layer deposition (ALD) process. The ALD process includes repeating cycles of alternately exposing the substrate 400 to a tungsten-containing precursor and exposing the substrate 400 to a reducing agent. In some embodiments, the processing region 221 is purged between the alternating exposures. In some embodiments, the processing region 221 is continuously purged. Examples of suitable tungsten-containing precursors include tungsten halides, such as tungsten hexafluoride (WF₆), tungsten hexachloride (WCl₆), or combinations thereof. In some embodiments, the tungsten-containing precursor includes WF₆, and the reducing agent may be a boron-containing agent, such as diborane (B₂H₆) or silane (SiH₄). In some embodiments, the tungsten-containing precursor comprises an organometallic precursor or a fluorine-free precursor, e.g., MDNOW (methylcyclopentadienyl-dicarbonylnitrosyl-tungsten), EDNOW (ethylcyclopentadienyl-dicarbonylnitrosyl-tungsten), tungsten hexacarbonyl (W(CO)₆), or combinations thereof.

For example, the tungsten-containing precursor and the reducing agent are each flowed into the processing region 221 for a duration of between about 0.1 seconds and about 10 seconds, such as between about 0.5 seconds and about 5 seconds. The processing region 221 may be purged between the alternating exposures by flowing a purge gas, such as Argon (Ar) or hydrogen gas, into the processing region 221 for a duration of between about 0.1 seconds and about 10 seconds, such as between about 0.5 seconds and about 5 seconds. The purge gas may be delivered from the deposition gas source 240 or from the bypass gas source 238. Typically, repeating cycles of the nucleation process continues until the nucleation layer 424 has a thickness of between about 10 Å and about 200 Å, such as between about 10 Å and about 150 Å, or between about 20 Å and about 150 Å. The nucleation layer 424 is disposed along sidewalls of the opening 405, such as over the adhesion layer 422. During the nucleation process, the processing volume 215 may be maintained at a pressure of less than about 120 Torr, such as of between about 900 mTorr and about 120 Torr, between about 1 Torr and about 100 Torr, or for example, between about 1 Torr and about 50 Torr. Exposing the substrate 400 to the tungsten-containing precursor includes flowing the tungsten-containing precursor into the processing region 221 from the deposition gas source 240 at a flow rate of about 100 sccm or less, such as about 10 sccm to about 60 sccm, or about 20 sccm to about 80 sccm. Exposing the substrate 400 to the reducing agent includes flowing the reducing agent into the processing region 221 from the deposition gas source 240 at a flow rate of about 200 sccm to about 1000 sccm, such as between about 300 sccm and about 750 sccm.

At activity 306, the substrate 400 is subjected to a radical treatment to form the passivation layer 426 on the nucleation layer 424 within the opening 405 shown in FIG. 4D. The passivation layer 426 inhibits, and in some embodiments, completely inhibits, the nucleation of tungsten on the passivation layer 426. The radical treatment 306 includes flowing an activated species formed in the first radical generator 206A, such as an activated nitrogen species such as N₂,NH₃, or a combination thereof, into the processing region 221. In some embodiments, the activated species are combined with an inert carrier gas, such as Ar, He, or a combination thereof, to form a radical treatment gas mixture. Without intending to be bound by theory, it is believed that the nitrogen from the activated nitrogen species are incorporated into portions of the nucleation layer 424, e.g., by adsorption of the nitrogen or by reaction with the metallic tungsten of the nucleation layer 424 to form a tungsten nitride (WN) passivation layer 426. The passivation layer 426 desirably delays (inhibits) further tungsten nucleation and thus subsequent tungsten deposition thereon.

In some embodiments, the passivation layer 426 only partially covers the nucleation layer 424, with a portion of the nucleation layer 424 near the bottom of the opening 405 being left uncovered. A field portion 426a of the passivation layer 426 may optionally be formed on the field 403 and an opening portion 426b is formed on the surface of the opening 405. For example, the field portion 426a may be formed to prevent deposition of tungsten on the field 403 of the substrate 400 in appreciable amounts. Reducing or eliminating tungsten deposition on the field 403 reduces material costs as well as reduces the time to conduct an operation to remove overburden. The opening portion 426b is a tungsten deposition inhibition profile to aid in the deposition of the tungsten gap fill layer 428 in the opening 405 without forming a void in activity 308. As shown in FIG. 4D, the opening portion 426b may extend partially into the first tier opening 402A from the second tier opening 402B. The opening portion 426b may terminate at or near the pinch point 430 of the nucleation layer 424, the pinch point 430 being the narrowest point within the opening 405 near the interface 406 after the nucleation layer 424 is deposited. In some embodiments, the opening portion 426b may extend past the pinch point 430. The desired inhibition effect on the field portion 426a and the desired inhibition profile in the opening 405 is achieved by controlling processing conditions within the processing chamber 202, such as temperature and pressure, and controlling the concentration, flux, and energy of the treatment radicals directed at the substrate surface.

For example, the radical treatment may create a passivation layer 426 with enhanced inhibition of the deposition of tungsten closer to the open end of the opening 405 than the bottom of the opening 405. The passivation layer 426 is formed to achieve the desired inhibitive effect to facilitate the bottom-up deposition of tungsten gap fill 428 within the opening 405 that is void-free and seam-free. The passivation layer 426 also mitigates the pinching effect to avoid forming a void. For example, the passivation layer 426 may prevent tungsten from being deposited on the opening portion 426b in appreciable amounts until tungsten has filled the first tier opening 402A. Once the first tier opening 402A is filled with tungsten, then additional tungsten is deposited on the tungsten filling the first tier opening 402A to fill the second tier opening 402B to form the tungsten gap fill layer 428. As shown in FIG. 4E, the portion of the tungsten gap fill layer 428 in the second opening 402B is formed over the opening portion 426b of the passivation layer 428.

The passivation layer 426 may be formed in a non-uniform thickness within the opening 405 such that the inhibitive effect is non-uniform. For example, the passivation layer 426 may be tapered such that the inhibitive effect decreases with the depth of the opening 405 such that tungsten nucleates on different parts of the passivation layer 426 at different rates to control the formation of the tungsten gap fill layer 428. For example, the rate of tungsten nucleation increases with the depth of the opening 405, such that the faster rate of tungsten nucleation occurs on the exposed part of the nucleation layer 424 at the bottom of the opening 405.

In some embodiments, exposing the nucleation layer 424 to the treatment radicals includes forming a treatment plasma 282A of a substantially halogen-free treatment gas mixture using the first radical generator 206A and flowing the effluent of the treatment plasma 282A into the processing region 221. In some embodiments, a flow rate of the treatment gas mixture into the first radical generator 206A, and thus the flow rate of the treatment plasma effluent, such as nitrogen gas, into the processing region 221, is about 1 sccm and about 3000 sccm, such as about 1 sccm and about 2500 sccm, such as about 1 sccm and about 2000 sccm, such as about 1 sccm and about 1000 sccm, such as about 1 sccm and about 500 sccm, such as about 1 sccm and about 250 sccm, such as about 1 sccm and about 100 sccm, such as about 1 sccm and about 75 sccm, such as about 1 sccm and about 50 sccm.

In some embodiments, the radical treatment includes exposing the substrate 400 to the treatment radicals for a period of about 2 seconds or more, such as about 2 seconds to about 30 seconds, such as about 5 seconds to about 20 seconds, such as about 10 seconds to about 15 seconds.

In some embodiments, a concentration of the activated radical species within the radical treatment gas mixture is about 0.1 vol. % to about 50 vol. %, such as about 0.2 vol. % to about 40 vol. %, about 0.2 vol. % to about 30 vol. %, about 0.2 vol. % and about 20 vol. %, or, for example, such as about 0.2 vol. % and about 10 vol. %, such as about 0.2 vol. % and about 5 vol. %.

In other embodiments, the treatment radicals may be formed using a remote plasma (not shown) which is ignited and maintained in a portion of the processing volume 215 that is separated from the processing region 221 by the showerhead 218, such as between the showerhead 218 and the lid plate 216. In those embodiments, the activated treatment gas may be flowed through an ion filter to remove substantially all ions therefrom before the treatment radicals reach the processing region 221 and the surface of the substrate 400. In some embodiments, the showerhead 218 may be used as the ion filter. In other embodiments, a plasma used to form the treatment radicals is an in-situ plasma formed in the processing region 221 between the showerhead 218 and the substrate 400. In some embodiments, e.g., when using an in-situ treatment plasma, the substrate 400 may be biased to control the directionality of and accelerate ions formed from the treatment gas, e.g., charged treatment radicals, towards the substrate surface.

In some embodiments, the radical treatment includes maintaining the processing volume 215 at a pressure of less than about 100 Torr while flowing the activated treatment gas thereinto. For example, during the radical treatment, the processing volume 215 may be maintained at a pressure of about 20 Torr or less, such as about 0.5 Torr and about 10 Torr, such as about 1 Torr and about 5 Torr.

Activity 308 represents forming the tungsten gap fill 428 in the opening 405 as shown in FIG. 4E using a pulse chemical vapor deposition (“pulse CVD”). Reducing the pressure and increasing the temperature have been found to improve the stress formed in a tungsten gap fill. However, simply increasing the temperature and reducing the pressure have diminishing returns. For example, low pressures, such as a vacuum condition, impact the quality of the gap fill and interferes with chucking the substrate 400 to the substrate support assembly 220. Some temperatures may degrade or adversely impact other features formed on the substrate 400. Additionally, some temperatures promote degradation of components of the processing system 200, resulting in increased maintenance costs. The pulse CVD process shown as activity 308 includes processing the substrate 400 at low pressures at moderate to high temperatures to leverage their stress reduction benefits. However, the pulse CVD 308 results in improved tungsten gap fill and lower stresses than can be achieved by only adjusting the temperature and pressure parameters.

The pulse CVD process, represented by 308, includes cyclically pulsing a first gas over a pulse time duration while a second gas concurrently flows into the processing region 221 and then purging the first and second gases from the processing region 221 with a purge gas over a purge time duration. The first gas and the second gas are supplied into the processing region 221 by the deposition gas source 240. The pressure within the processing volume 215 is between about 0.7 Torr and about 15 Torr, such as 1 Torr, 1.5 Torr, 2 Torr, 2.5 Torr, 3 Torr, 3.5 Torr, 4 Torr, 4.5 Torr, 5 Torr, 5.5 Torr, 6 Torr, 6.5 Torr, 7 Torr, 7.5 Torr, 8 Torr, 8.5 Torr, 9 Torr, 9.5 Torr, 10 Torr, 10.5 Torr, 11 Torr, 11.5 Torr, 12 Torr, 12.5 Torr, 13 Torr, 13.5 Torr, 14 Torr, 14.5 Torr. The temperature within the processing region 221 may be between 400° C. and 500° C. and the heat may be supplied by the heater 229, first heater 263, and/or second heater 264.

In some embodiments, the first gas is a tungsten containing precursor, such as tungsten hexafluoride. In some embodiments, the first gas is hydrogen gas. In some embodiments, the first gas is a mixture of a tungsten containing precursor and hydrogen gas, such as a mixture of tungsten hexafluoride and hydrogen gas. The pulse time duration may be between about 0.3 s and about 2 s, such as about 0.5 s, about 1 s, and about 1.5 s.

In some embodiments, the second gas is a mixture of hydrogen gas and an inert gas, such as Argon when the first gas includes a tungsten containing precursor. In some embodiments, the second gas is a tungsten containing precursor, such as tungsten hexafluoride, and an inert gas, such as Argon. In some embodiments, the second gas is an inert gas when the first gas is a mixture of a tungsten containing precursor and hydrogen gas.

In some embodiments, the purge gas is an inert gas such as Argon. Alternatively, the purge gas may be the second gas, or the purge gas may be composed of the same component gases but at a different concentration. The purge gas may be supplied into the processing region 221 from the purge gas source 237 in some embodiments. The purge gas may be supplied by the deposition gas source 240, in that the processing region 221 is purged by the continued flow of the second gas into the processing chamber 202 after the first gas pulse stops which causes the first gas to flow from the processing region 221 and out of the exhaust 217. The pulse time duration may be between about 0.5 s and about 5 s, such as about 1 s, such as about 1.5 s, such as about 2 s, such as about 2.5 s, such as about 3 s, such as about 3.5 s, such as about 4 s, and such as about 4.5 s.

Without being bound by theory, it is believed that fluorine impurities in the tungsten gap fill 428 contribute to the stress. Without being bound by theory, it is believed that the purging with a purge gas that does not include fluorine after each pulse reduces the development of fluorine impurities, such as by reducing the time available for tungsten hexafluoride to interact with the developing tungsten gap fill. Additionally, it is believed that reducing the stress in the tungsten gap fill results in smaller grain size.

In one embodiment, the first gas is tungsten hexafluoride and the second gas is a mixture of hydrogen gas and Argon. For example, between about 50 sccm and 1200 sccm of tungsten hexafluoride is pulsed into the processing region 221 over the pulse time duration into a concurrently flowing mixture of between about 200 sccm to 6000 sccm hydrogen gas and between about 350 sccm to about 8000 sccm of Argon. The processing region 221 is then purged with a mixture of hydrogen gas and Argon.

In one embodiment, the first gas is hydrogen gas and the second gas is a mixture of tungsten hexafluoride and Argon. For example, between about 200 sccm to 6000 sccm hydrogen gas is pulsed into the processing region 221 over the pulse time duration into a concurrently flowing mixture of between about 50 sccm and 1200 sccm of tungsten hexafluoride and about between 350 sccm to about 8000 sccm of Argon. The processing region 221 is then purged with a mixture of tungsten hexafluoride and Argon. For example, the processing region 221 may be purged with mixture of 3000 sccm to about 8000 sccm of Argon and between 100 sccm and 900 sccm of tungsten hexafluoride. Without being bound by theory, it is believed that pulsing the tungsten hexafluoride into the flowing hydrogen gas allows for the deposition reaction to be more complete, which reduces the development of fluorine impurities in the deposited tungsten gap fill layer 428.

In one embodiment, the first gas is a mixture of tungsten hexafluoride and hydrogen gas and the second gas is Argon. For example, a mixture of between about 50 sccm and 1200 sccm of tungsten hexafluoride and between about 200 sccm to 6000 sccm hydrogen gas is pulsed into the processing region 221 over the pulse time duration into between about 350 sccm to about 8000 sccm of concurrently flowing Argon. The processing region 221 is then purged with Argon. For example, the processing region 221 may be purged with 3000 sccm to about 8000 sccm of Argon.

It has been observed that a pulse CVD process 308 comprising a first gas of hydrogen and a second gas that is a mixture of tungsten hexafluoride and Argon has improved gap fill, e.g., less instances of voids, as compared to other embodiments of the CVD process 308. However, the other embodiments of the pulse CVD process 308 have satisfactory gap fill qualities as compared to tungsten gap fills deposited by conventional techniques.

The pulse CVD process 308 may be performed over one or more cycles, such as between 1 and 1000 cycles. The number of cycles can be based on the aspect ratio of the opening, as more cycles may be necessary the deeper the opening. In some embodiments, the temperature and pressure may be maintained the same for each cycle. In some embodiments, the temperature and pressure may vary between cycles.

The pulse CVD process 308 results in a tungsten gap fill 428 with reduced stress. In some embodiments, the tungsten gap fill 428 formed by the pulse CVD process 308 has an internal stress between about 0 MPa and 200 MPa, such as between 0 MPa and 150 MPa, such as 0 MPa and 100 MPa, such as about 0 MPa and 50 MPa, such as about 0 MPa and 40 MPa, such as about 0 MPa and 30 MPa, such as about 0 MPa and 20 MPa, such as about 0 MPa and 10 MPa, such as about 0 MPa and 5 MPa, such as about 0 MPa and 1 MPa, such as about 0 MPa and about 0.5 MPa. In some embodiments, the tungsten gap fill 428 has an internal stress that is neutral, e.g., 0 MPa, or substantially neutral.

A chemical mechanical polishing (CMP) process may be used to remove overburden material, such as portions of the adhesion layer 422, the nucleation layer 424, the passivation layer 426, and tungsten gap fill layer 428 that extends above the field 403 of the substrate 400 following depositing the tungsten gap fill layer 428 into the opening 405.

The processing system 200 is configured to perform each activity of process 300 to form a void-free and seam-free tungsten gap fill with low stress. The process 300 can be performed without removing the substrate 400 from the processing system 200. The treatment gases used to perform the individual processes of the process 300, and to clean residues from the interior surfaces of the processing chamber 202, are delivered to the processing chamber 202 using the gas delivery system 204 fluidly coupled thereto. In other embodiments, each activity in process 300 can be performed in a different processing system, such as being performed in a cluster tool with multiple processing systems 200.

In some embodiments, process 300 is performed on a substrate having a single tier layer rather than a multi-tier layer.

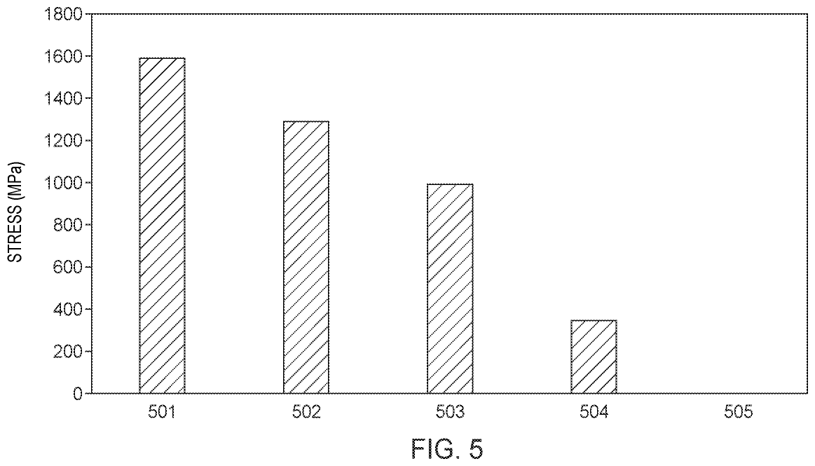

FIG. 5 includes Bar Graph 500 that illustrates the stress in a tungsten feature, e.g., tungsten gap fill, of about 12000 Angstroms (Å) thick formed on a substrate under differing process conditions. The Y-axis represents stress in megapascals (MPa) in tungsten features labeled as 501, 502, 503, 504, and 505 on the X-axis. Each tungsten feature 501, 502, 503, 504, and 505 is formed by different processes.

Tungsten feature 501 was deposited by a conventional CVD tungsten deposition process that includes concurrently flowing tungsten hexafluoride and hydrogen gas at 400° C. and 300 Torr. As shown in FIG. 5, Tungsten feature 501 has a stress of about 1600 MPa. Tungsten feature 502 was formed by a CVD process that includes concurrently flowing tungsten hexafluoride and hydrogen gas at 400° C. and 5 Torr, which resulted in a stress of about 1300 MPa. Tungsten feature 502 has less stress than tungsten feature 501. Tungsten feature 503 was formed by a CVD process that includes concurrently flowing tungsten hexafluoride and hydrogen gas at 450° C. and 5 Torr, which resulted in a stress of about 1000 MPa. As compared to tungsten feature 502, tungsten feature 503 has a lower stress caused by the increase in temperature by 50° C. Tungsten feature 504 was formed by a CVD process including concurrently flowing tungsten hexafluoride and hydrogen gas at 540° C. and 5 Torr, which resulted in a stress of about 350 MPa. Tungsten feature 504 has a lower stress as compared to tungsten features 502, 503 as a result of a further increase in temperature.

Feature 505 was formed using the pulse CVD process 308 performed at 500° C. and at a pressure of about 0.8 Torr. The first gas included a mixture of 50 sccm tungsten hexafluoride and 200 sccm of hydrogen gas. The second gas included Argon at 350 sccm. The pulse time duration of the first gas was 0.5 seconds. The processing region 221 was purged with 350 sccm of Argon, and the purge time duration was 2 seconds. The tungsten feature 505 has a stress of about 0 MPa. Thus, the pulse CVD process 308 further reduces the stress of the Tungsten feature beyond the stress reduction benefits caused by a low pressure and high temperature.

While the foregoing is directed to embodiments of the present disclosure, other and further embodiments of the disclosure may be devised without departing from the basic scope thereof, and the scope thereof is determined by the claims that follow.

1. A method of forming a structure on a substrate, comprising:
forming a nucleation layer within an opening of a substrate within a processing chamber;
forming a passivation layer on at least a portion of the nucleation layer by introducing radical treatment into the processing chamber; and
forming a tungsten fill layer within the opening over the passivation layer and the nucleation layer, wherein the tungsten fill layer is formed by a plurality of treatment cycles, each treatment cycle including:
pulsing a first gas at the substrate for a pulse time duration while concurrently flowing a second gas over the substrate, wherein the second gas includes a tungsten containinq precursor; and
purging the first gas and the second gas by flowing a purge gas over the substrate for a purge time duration.

2. The method of claim 1, wherein the purge gas is the second gas.

3. The method of claim 1, wherein the treatment radicals are an activated nitrogen containing species.

4. The method of claim 1, wherein the treatment radicals are nitrogen gas.

5. The method of claim 1, wherein forming the passivation layer includes introducing the radical treatment into a processing region from a radical generator attached to a lid assembly of the processing chamber.

6. (canceled)

7. The method of claim 1, wherein the tungsten containinq precursor is tungsten hexafluoride, wherein the first gas is hydrogen gas, the second gas is a first mixture of tungsten hexafluoride and Argon, and the purge gas is a second mixture of tungsten hexafluoride and Argon.

8. (canceled)

9. The method of claim 1, wherein the pulse time duration is between about 0.3 seconds and about 2 seconds and the purge time duration is between about 0.5 seconds and about 5 seconds.

10. The method of claim 1, wherein the tungsten fill layer has a stress between 0 MPa and 200 MPa.

11. A method of forming a structure on a substrate, comprising:
depositing a tungsten fill layer into an opening of a substrate having an internal stress less than 200 MPa, wherein the tungsten fill layer is formed by a plurality of treatment cycles, each treatment cycle including:
pulsing a first gas at the substrate for a pulse time duration while concurrently flowing a second gas over the substrate; and
purging the first gas and the second gas by flowing a purge gas over the substrate for a purge time duration.

12. The method of claim 11, wherein the first gas is tungsten hexafluoride, the second gas is a mixture of hydrogen gas and Argon, and the purge gas is a mixture of hydrogen gas and Argon.

13. The method of claim 11, wherein the first gas is hydrogen gas, the second gas is a first mixture of tungsten hexafluoride and Argon, and the purge gas is a second mixture of tungsten hexafluoride and Argon.

14. The method of claim 11, wherein the first gas is a mixture of tungsten hexafluoride and Argon, the second gas is Argon, and the purge gas is Argon.

15. The method of claim 11, wherein the pulse time duration is between about 0.3 seconds and about 2 seconds and the purge time duration is between about 0.5 seconds and about 5 seconds.

16. The method of claim 11, further comprising:
forming a passivation layer within the opening by injecting an activated nitrogen species from a radical generator attached to a lid of a processing chamber into a processing region of the processing chamber.

17. A method of forming a structure on a substrate, comprising:
forming a nucleation layer on a substrate, wherein a first portion of the nucleation layer is deposited in an opening of the substrate and a second portion of the nucleation layer is deposited on a field of the substrate;
forming a passivation layer on the nucleation layer by exposing the nucleation layer to a radical treatment, wherein the passivation layer prevents tungsten deposition on the second portion of the nucleation layer; and
forming a tungsten fill layer within the opening over the passivation layer and the nucleation layer, wherein the tungsten fill layer is formed by a plurality of treatment cycles, each treatment cycle including:
pulsing a first gas at the substrate for a pulse time duration while concurrently flowing a second gas over the substrate; and
purging the first gas and the second gas by flowing a purge gas over the substrate for a purge time duration.

18. The method of claim 17, wherein the first gas is tungsten hexafluoride, the second gas is a mixture of hydrogen gas and Argon, and the purge gas is a mixture of hydrogen gas and Argon.

19. The method of claim 17, wherein the first gas is hydrogen gas, the second gas is a first mixture of tungsten hexafluoride and argon, and the purge gas is a second mixture of tungsten hexafluoride and Argon.

20. The method of claim 17, wherein the tungsten fill layer has a stress between 0 MPa and 200 MPa.

21. The method of claim 1, wherein a portion of the passivation layer prevents deposition of tungsten fill layer on a field of the substrate in appreciable amounts.

22. The method of claim 1, wherein the purge gas includes the tungsten containing precursor.
